(19) United States
(12) Patent Application Publication
(10) Pub. No.: US 2021/0191832 A1
(43) Pub. Date: Jun. 24, 2021

(54) INTELLIGENT MEMORY DEVICE TEST RESOURCE

(71) Applicant: MICRON TECHNOLOGY, INC., Boise, ID (US)

(72) Inventor: Gary D. Hamor, Mead, CO (US)

(21) Appl. No.: 16/852,229

(22) Filed: Apr. 17, 2020

Related U.S. Application Data
(60) Provisional application No. 62/949,997, filed on Dec. 18, 2019.

(51) Int. Cl. G06F 11/273; G06F 11/22; G06F 11/30

(52) U.S. Cl. CPC G06F 11/2733; G06F 11/3058; G06F 11/3037; G06F 11/2221

(57) ABSTRACT

A memory device test resource includes a dedicated processing device for the memory device test resource, the dedicated processing device configured to facilitate testing of a memory device of a memory sub-system coupled to the memory device test resource. The memory device test resource further includes a memory sub-system interface port coupled to the dedicated processing device and configured to couple the memory device test resource to the processing device, a test condition component coupled to the dedicated processing device and configured to generate a test condition at the memory device test resource, and a test resource monitoring component coupled to the dedicated processing device and configured to monitor one or more conditions at the memory device test resource.

### RELATED APPLICATIONS

This application claims the benefit of U.S. Provisional Application No. 62/949,997, filed Dec. 18, 2019, the entire contents of which are hereby incorporated by reference herein.

### TECHNICAL FIELD

Embodiments of the disclosure relate generally to memory sub-systems, and more specifically, relate an intelligent memory device test resource.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system, in accordance with some embodiments of the present disclosure.

FIG. 2 is a test platform to perform a test of memory devices, in accordance with some embodiments of the present disclosure.

FIG. 3 is an example memory device test resource of a memory device test rack, in accordance with some embodiments of the present disclosure.

FIG. 4 is an example connection of a memory sub-system to a memory device test resource, in accordance with some embodiments of the present disclosure.

FIG. 5 is a flow diagram of an example method for an intelligent memory device test resource, in accordance with some embodiments of the present disclosure.

FIG. 6 is a flow diagram of an example method for a memory sub-system engaged with an intelligent memory device test resource, in accordance with some embodiments of the present disclosure.

FIG. 7 is a flow diagram of an example method for a resource allocator operatively coupled to each processing device of a test resource of a test rack, in accordance with some embodiments of the present disclosure.

FIG. 8 is a block diagram of an example computer system, in which embodiments of the present disclosure can operate.

### DETAILED DESCRIPTION

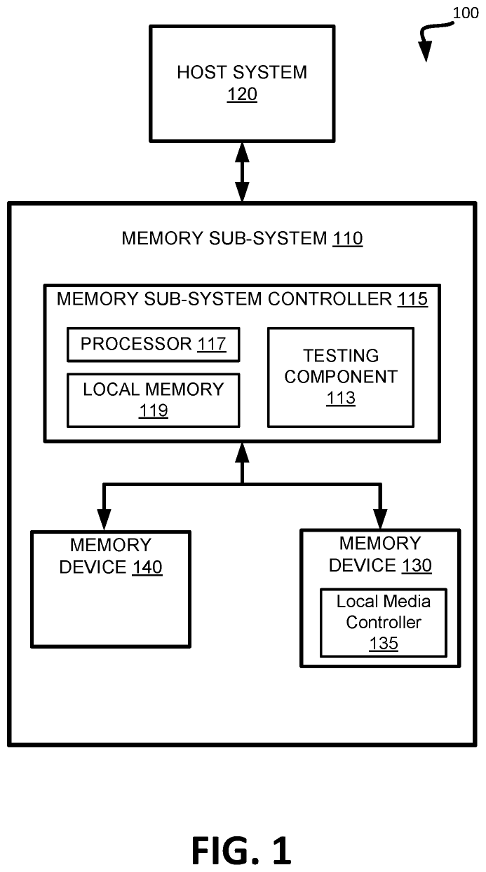

Aspects of the present disclosure are directed to an intelligent memory device test resource. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

Memory devices that are used in a memory sub-system can be tested before being utilized in the memory sub-system. In a conventional test process, the memory devices can be placed into a chamber (e.g., an oven) that tests the memory device under various temperature conditions. For example, a single chamber can be used to test multiple memory devices at a single time at a particular temperature. The test process can instruct various operations to be performed at the memory devices at the particular temperature. Such operations include, but are not limited to, read operations, write operations, and/or erase operations. The performance and behavior of the memory devices can be observed while the test process is performed. For example, performance characteristics (e.g., read or write latencies) and reliability of data stored at the memory devices can be measured and recorded during and after the test process. However, since the chamber can only subject the memory devices to a single temperature at any particular time, the testing of the memory devices at many different temperatures can require a large amount of time as the test process will need to be performed for each target test temperature. Additionally, the chamber can only perform a single test process at a time. As such, performing different tests of the memory devices at different operating conditions (e.g., different temperatures) can utilize a large amount of time if many different conditions of the test process for the memory devices to be tested.

In some conventional memory device testing systems, memory devices can be tested using a testing component that includes a temperature control component. The temperature control component is used to subject the memory device to a particular temperature condition. In some testing components, only a temperature control component is included and the memory device is not subjected to any other conditions during memory device testing. Multiple testing components can be included in a testing rack, where each testing component of the testing rack is coupled to a local testing module. The local testing module can facilitate testing for each memory sub-system coupled to a testing component of the testing rack. For example, the local testing module cause various operations to be performed for memory devices at multiple testing components at one or more temperature conditions. As the local testing module facilitates testing for each memory sub-system coupled to a testing component of the testing rack, an entire testing rack can be unusable during maintenance or failure of the single local testing module.

In some instances each testing rack can include hundreds of testing components. The local testing module can maintain a log of testing components available for testing of a memory device. As the log of testing components can include hundreds of entries (i.e., an entry for each testing component), significant memory resources can be used by the local testing module to maintain the log. The local testing module can reference the log of available testing components in response to each request for testing of a memory device at the memory rack. Each reference of the log can increase the latency of a testing process at the testing rack, thereby increasing the latency of the overall testing system.

Aspects of the present disclosure address the above and other deficiencies by providing an intelligent memory device test resource. A distributed test platform can include multiple memory device test racks. Each test rack can include multiple test resources where each test resource includes a processing device dedicated to facilitating memory device testing at the test resource. The processing device can facilitate testing of memory devices included in memory sub-systems coupled to the memory device test resource. Each test resource further includes one or more test condition components, one or more test resource monitoring components, and a memory sub-system interface port. A memory sub-system, including a memory device to be tested, can be coupled to a test resource by engaging with the memory sub-system interface port. In response to detecting the memory sub-system is coupled to the test resource, the processing device of the test resource can transmit test instructions to the memory sub-system including one or more operations to be performed at the memory device. A memory sub-system controller of the memory sub-system can cause the one or more operations to be performed at the memory device. The memory sub-system controller can generate a set of test results for the performance of each operation at the memory device. After the operations are performed at the memory sub-system, the memory sub-system controller transmits the set of test results to the processing device memory device test resource.

Each test resource includes a test condition component. A test condition component can include at least one of a temperature controller or a voltage controller. A temperature controller is configured to control a temperature of the memory device during testing. The voltage controller is configured to control a voltage of the power supply signal provided to the memory sub-system during testing. The processing device of the test resource can cause one or more conditions to occur at the test resource. For example, at least one of the temperature controller or the voltage controller can cause a first condition to occur prior to the initiation of testing at the memory device. During testing of the memory device, the temperature controller and/or the voltage controller can cause a second condition to occur. In response to detecting that the second condition has occurred, the memory sub-system controller can generate a second set of test results, where the second set of test results are related to the performance of an operation performed at the memory device operating at the second condition.

Advantages of the present disclosure include, but are not limited to, a decrease in an amount of time that the test platform is utilized to perform test of the memory devices. As many different tests can be performed at the test platform to test many different conditions (e.g., different temperatures, different power supply signal voltages, etc.) during the performance of many different sequences of operations, the testing of memory devices can be considered to be more robust as the reliability and performance of the memory devices can be tested by performing many different and concurrent tests. Further, as the processing device of each test resource facilitates testing of a memory device, one or more other test resources can be available for testing of memory devices if a particular test resource or section of test resources is unavailable (e.g., for maintenance, etc.). Further, a log of available test resources is not maintained for each test resource of a test rack and therefore is not referenced in response to each request to test a memory device at a test resource of the test rack. As such, each test for each memory device can be performed in less time, thereby decreasing overall system latency. The reliability of the memory device can also increase as any potential defects of flaws can be identified and later addressed in the design or manufacturing of the memory devices that are to be available to customers.

As each test resource includes a dedicated processing device, a memory device can be tested at a test resource that is removed from a test board of the test rack. For example, an operator of the test platform can cause a test resource to be removed from a test board of the test rack. The operator can provide a power source and a network connection to the test resource (e.g., by connecting the test resource to a computing device). In response to the test resource receiving the power source and the network connection, a memory sub-system can be coupled to the test resource. A test can be performed for a memory device included in the coupled memory sub-system while the test resource is disconnected from the test board of the test rack.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory devices such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

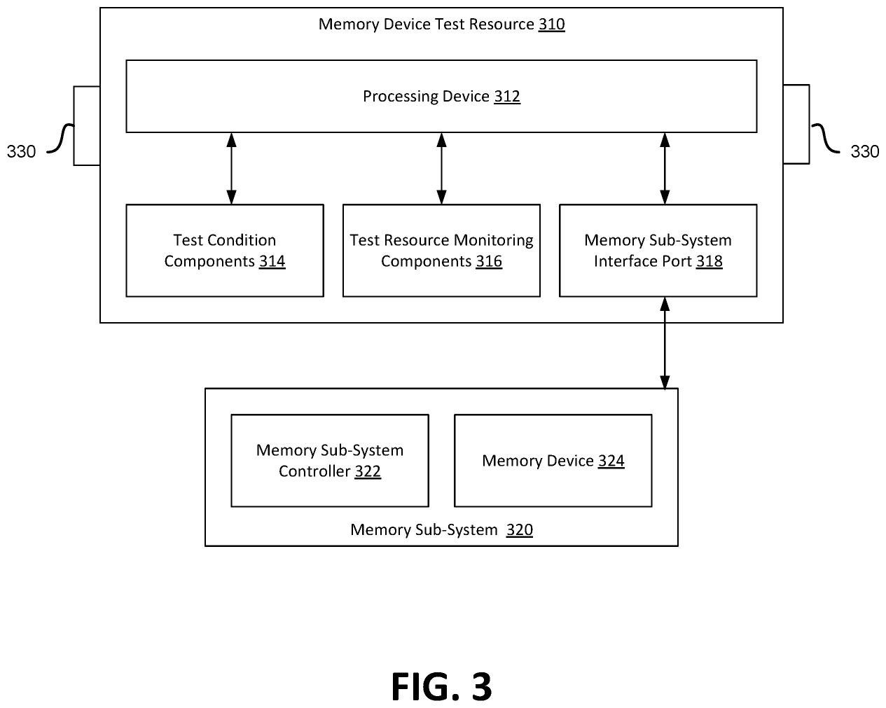

The memory sub-system 110 includes a testing component 113 which performs tests on a memory device of sub-system 110, such as memory device 130. Memory sub-system 110 can couple to a memory device test resource of a test rack, such as memory device test resource 310 of FIG. 3. Each memory device test resource of the test rack can include a processing device dedicated to facilitating testing of a memory device at the memory device test resource. Testing component 113 receives, from the processing device of the test resource, one or more instructions for a test to be performed at memory device 130. The test instructions can include one or more operations to be performed at memory device 130, such as read operations, write operations and/or erase operations. Testing component 113 causes the performance of the one or more operations at memory device 130. During the performance of the one or more operations, testing component 113 collects data relating to the performance of the one or more operations. Testing component 113 generates a first set of test results based on the data collected during the performance of the one or more operations. In some embodiments, testing component 113 detects one or more conditions of memory sub-system 110 have changed during a performance of the one or more operations at memory device 130. For example, a temperature of memory sub-system 110 can increase from a first temperature to a second temperature during performance of the one or more operations. In some embodiments, a test condition component of the test resource can change the one or more conditions of memory sub-system 110. In such embodiments, testing component 113 generates a second set of test results based on the data collected during the performance of the one or more operations performed at the second condition. After testing component 113 generates the first set of test results and/or the second test of test results, testing component 113 transmits each set of test results to the processing device of the test resource.

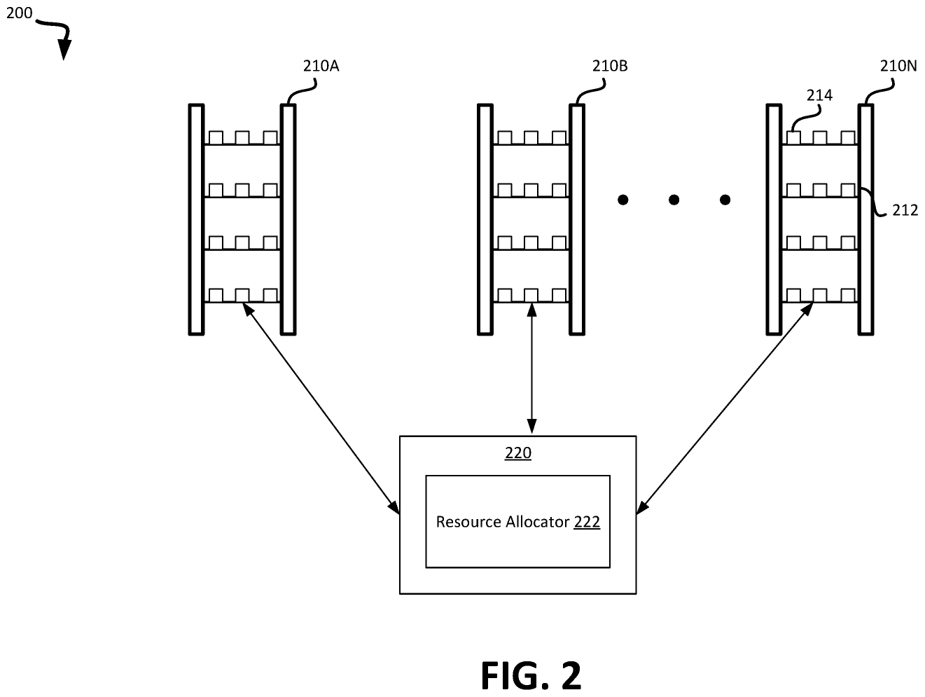

FIG. 2 illustrates a test platform 200 to perform a test of memory devices in accordance with some embodiments of the present disclosure. Test platform 200 can include one or more test racks 210A, 210B, and 210N. Each of the test racks 210A, 210B, and 210N (referred to as test racks 210) can include multiple test boards 212 where each test board 212 includes one or more test resources 214 (i.e., test sockets). The test platform 200 can include any number of racks 210, test boards 212, or test resources 214. As shown, a test board 212 can include one or more test resources 214. Although three test resources 214 are shown, a test board 212 can include any number of test resources 214. Each test resource 214 can include a memory sub-system that has been coupled to the respective test resource 214.

One or more tests can be performed for a memory device of a memory sub-system that has coupled to a test resource 214. Each test resource 214 can include a separate and dedicated processing device that is used to facilitate testing of the memory device. For example, rather than there being a shared processing device for each rack 210 or even for each test board 212, there can be an individual processing device for each test resource 214. The processing device can receive instructions to be executed in performance of the test. The instructions can include one or more operations to be performed at a memory device of the memory sub-system. The instructions can also include one or more conditions to be applied to the memory sub-system during testing.

In some embodiments, a test resource 214 can be removed from a test board 212 and testing of a memory device can be performed at the removed test resource 214 separately from test rack 210. Test board 212 and test resource 214 can include a locking mechanism configured to secure a test resource 214 to test board 212. A first component of the locking mechanism can be disposed at an exterior portion of test resource 214. A second component of the locking mechanism can be included at test board 212. Test resource 214 can be secured to test board 212 in response to the first component engaging with the second component of the locking mechanism. Similarly, test resource 214 can be removed from test board 212 in response to the first component disengaging from the second component of the locking mechanism.

As test resource 214 includes a dedicated processing device to facilitate memory device testing, testing can be performed for a memory device of a memory sub-system even when the test resource 214 is removed from test board 212 and test rack 210. For example, test resource 214, once removed from test board 212, can be connected to a power supply and a network connection that is separate from test board 212 and test rack 210 (e.g., a separate computing device). In response to test resource 214 connecting to the power supply and the network connection, a processing device of test resource 214 can facilitate testing of a memory device of a memory sub-system coupled to the removed test resource 214.

A resource allocator component 222 can receive (e.g., from a user) instructions including a sequence of one or more operations and/or conditions of the test that is to be performed for a memory device of a memory sub-system. Resource allocator component 222 can determine particular test resources 214 across the different test racks 210 that can be used to perform the test. For example, the resource allocator component 222 can query each processing device of each test resource 214 of each test rack 210 to determine particular test resources 214 across the different test racks 210 that can be used to perform the test. In some embodiments, the resource allocator component 222 can be provided by a server 220 connected to each of the processing devices of test resources 214. In some embodiments, the server 220 is a computing device or system that is coupled with each processing device of each test resource 214 over a network.

In response to a memory sub-system being coupled to a particular test resource 214, resource allocator component 222 can transmit the received instructions to the processing device of particular test resource 214. In some embodiments, the resource allocator component 222 can transmit the received instructions to the processing device prior to the memory sub-system being coupled to the test resource 214. After the test has been performed for the memory device of the memory sub-system, the processing device of the test resource 214 can transmit data associated with the results of the test to the resource allocator component 222, for transmission and/or presentation to the requesting user. The data associated with the results of the test can include data associated with the performance of the operations at the memory device of the memory sub-system. In some embodiments, the data associated with the results of the test can further include data associated with one or more conditions of the test resource 214 during the performance of the test.

In some instances, a processing device of a test resource 212 can be unavailable to facilitate testing at the test resource 214. In some embodiments, a processing device of another test resource 214 can be available to facilitate testing. For example, a processing device of a first test resource 214 can be unavailable to facilitate testing of a memory device. A second test resource 214 can be identified, where the second test resource 214 includes a processing device that is available to facilitate testing of the memory device. Memory devices of memory sub-systems can be tested at the second test resource 214 until the processing device of the first test resource 214 is available to facilitate testing.

FIG. 3 is an memory device test resource 310 of a memory device test rack, in accordance with some embodiments of the present disclosure. For example, memory device test resource 310 can be one implementation of any of the memory device test resources 214 illustrated in FIG. 2. Test resource 310 can include a dedicated processing device 312 for facilitating testing at test resource 310 one or more test conditions components 314, one or more test resource monitoring components 316, and a memory sub-system interface port 318 (referred to herein as port 318).

As described previously, processing device 312 can facilitate testing of a memory device 324 of a memory sub-system 320 coupled to a test resource 310. Processing device 312 can receive one or more test instructions to be executed in the performance of a test of memory device 324. The one or more test instructions can include one or more operations to be performed at the memory device 324. In some embodiments, the one or more test instructions can further include one or more conditions to be applied to memory sub-system 320 during performance of the test.

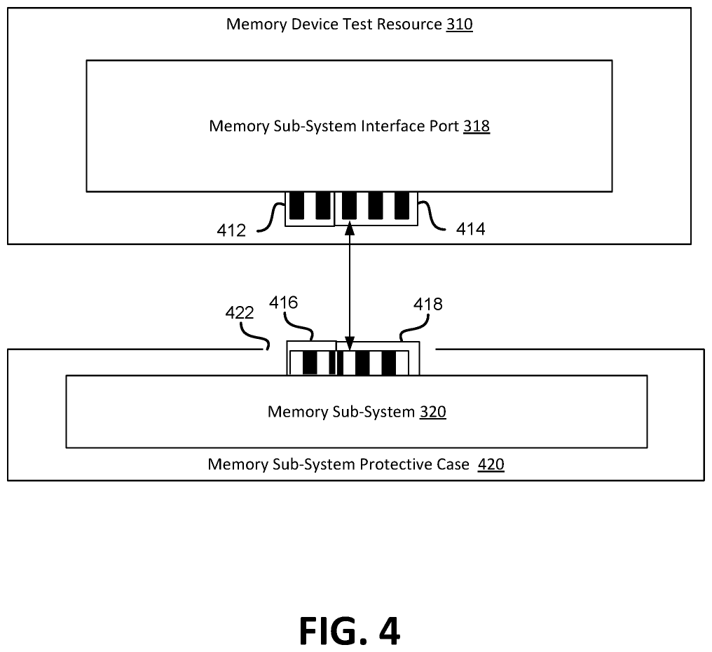

Memory sub-system 320 can be coupled to test resource 310 by engaging with port 318. Port 318 can include a first set of one or more serial input/output (IO) pins configured to couple to corresponding serial IO receptacles of memory sub-system 320. Port 318 can further include a second set of one or more IO pins configured to couple to corresponding IO receptacles of memory sub-system 320. Further details regarding port 318 are further described with respect to FIG. 4.

In response to detecting that memory sub-system 320 has coupled to port 318, processing device 312 can cause a power supply signal to be provided to memory sub-system 320 via port 318 at a first voltage condition. In some embodiments, the power supply signal can include electricity. Processing device 312 can further transmit one or more test instructions, including one or more operations to be performed at memory device 324, to memory sub-system 320 via port 318.

In some embodiments, processing device 312 can cause memory sub-system 320 to initiate a re-boot process prior to the test being performed at memory device 324. In such embodiments, processing device can transmit a signal to memory sub-system controller 322, via port 318, instructing memory sub-system controller 322 to initiate the re-boot process. Memory sub-system controller 322, in response to receiving the signal, can initiate the re-boot process. Memory sub-system controller 322 can initiate the test after initiating the re-boot process. In other or similar embodiments, processing device 312 does not transmit a signal to memory sub-system controller 322 to initiate the re-boot process and instead can transmit a signal to memory sub-system controller 322, via port 318, instructing memory sub-system controller 322 to initiate the test at memory device 324. Memory sub-system controller 322 can initiate the test at memory device 324 in response to receiving the signal from processing device 312, via port 318.

Prior to the initiation of the test at memory device 324, processing device 312 can cause one or more conditions of test resource 310 to be applied to memory sub-system 320. In some embodiments, processing device 312 can cause the one or more test conditions to be applied to memory sub-system 320 in accordance with the one or more test instructions received from a resource allocator, such as resource allocator component 222 of FIG. 2. Test condition components 314 can generate the one or more test conditions. In some further embodiments, a test condition component 314 can include at least one of a temperature controller or a voltage controller. In some embodiments, the temperature controller can include one or more fans configured to cool ambient air surrounding the memory sub-system embedded within the test resource. In other or similar embodiments, the temperature controller can be a dual Peltier device (e.g., two Peltier devices) that utilize a Peltier effect to apply a heating or cooling effect at a surface of the dual politer device that is coupled to the memory sub-system. In another example, a voltage condition can be applied to the memory sub-system 320 by a voltage controller. In some embodiments, the voltage controller can include one or more power supplies configured to supply different voltages to the memory sub-system 320 via port 318.

In some embodiments, the one or more test instructions can include a first condition to be applied to memory sub-system during performance of the test. The first condition can be created by a test condition component 314 prior to or during performance of the test at memory device 324A. In some embodiments, the one or more test instructions can include at least a second condition to be applied to memory sub-system 320 during performance of the test at memory device 324. Test condition components 314 can cause the first condition to be changed to the second condition during testing of memory device 324.

Test resource monitoring components 316 can monitor one or more conditions within test resource 310. In some embodiments, test resource monitoring components 316 can monitor a condition generated by a test condition component 314. For example, a temperature monitoring component can measure a temperature of test resource 310, where the temperature is generated by a temperature controller of test resource 310. Test resource monitoring components 316 can include at least one of a temperature monitoring component configured to monitor a temperature of test resource 310, a voltage monitoring component configured to monitor a voltage of a power supply signal provided to memory sub-system 320 via port 318, a current monitoring component configured to monitor a current of the power supply signal provided to memory sub-system 320 via port 318, or a humidity monitoring component configured to monitor a humidity of test resource 310.

As described previously, memory sub-system controller 322 can receive one or more test instructions including one or more operations to be performed at memory device 324 from processing device 312. In response to receiving an instruction from processing device 312 to initiate the test at memory device 324, memory sub-system controller 322 can cause one or more operations of the received test instructions to be performed at memory device 324. Memory sub-system controller 322 can generate one or more sets of test results associated with the performance of the one or more operations at memory device 324. Memory sub-system controller 322 can generate at a first set of test results, in accordance with previously described embodiments.

In some embodiments, memory sub-system controller 322 can generate at least a second set of test results. As the one or more operations are performed at memory device 324, memory sub-system controller 322 can detect a change from a first condition to a second condition, where a test condition component 314 caused the change from the first condition to the second condition, in accordance with previously described embodiments. In some embodiments, memory sub-system controller 322 can detect the change in response to receiving a signal from processing device 312. In other or similar embodiments, memory sub-system controller 322 can detect the change in response to receiving a signal from a sensor of memory sub-system 320 that a condition of memory sub-system 320 has changed from the first condition to the second condition. In response to detecting the change from the first condition to the second condition, memory sub-system controller 322 can generate a second set of test results. The second set of test results can correspond to a performance of one or more operations of the test instructions at the second condition.

In response to completion of the test at memory device 324, memory sub-system controller 322 can transmit one or more sets of test results to processing device 312. In response to receiving the one or more sets of test results, processing device 312 can transmit each set of test results to another computing device, such as server 220 of FIG. 2, for transmission and/or presentation to a user requesting the test for memory device 324.

In some embodiments, processing device 312 can include a memory component (not shown) that is configured to store data associated with one or more conditions of the test resource 310 during the performance of the test at memory device 324. In such embodiments, processing device 312 can transmit, along with each set of test results, data associated with the one or more conditions of test resource 310 during the performance of the test for memory device 324.

In some embodiments, test resource 310 can be removed from a test rack 210. Test resource 310 can include one or more components of a fastening mechanism disposed at an exterior of a body test resource, such as fastening components 330. Fastening components 330 can be first components of the fastening mechanism that are configured to engage with second components of the fastening mechanism. In some embodiments, the second components of the fastening mechanism can be included in a test board of a test rack 210. Test resource 310 can be secured to the test board of test rack 210 when fastening components 330 engage with the second components of the fastening mechanism. Similarly, test resource 310 can be removed from the test board of test rack 210 when fastening components 330 disengage with the second components of the fastening mechanism. Test resource 310 can be connected to a power supply and a network connection that is separate from the test rack 210. For example, an operator of test rack 210 can cause fastening components 330 of test resource 310 to disengage from the second components of the fastening mechanism of the test board and connect test resource 310 to a power supply and a network connection that is separate from the test rack 210 (e.g., at a separate computing device). In response to test resource 310 being connected to the power supply and the network connection that is separate from the test rack 210, processing device 312 can facilitate testing of memory device 324, in accordance with previously disclosed embodiments.

FIG. 4 is an example connection of a memory device test resource 310 to a memory sub-system 320, in accordance with some embodiments of the present disclosure. Port 318 can be configured to transmit a power supply signal to memory sub-system 320. Port 318 can be further configured to transmit to and/or receive instructions and data from memory sub-system 320.

Port 318 can include a first set of pins 412 that are configured to couple to a first set receptacles 416 of memory sub-system 320. Each of the first set of pins 412 can be configured to transmit a power supply signal (e.g., electricity) to memory sub-system 320. The first set of receptacles 416 can be configured to receive the power supply signal from test resource 310 transmitted via port 318. In some embodiments, each of the first set of pins 412 can be non-serial input/output (IO) pins. In other or similar embodiments, each of the first set of pins 412 can be pins of a high speed serial interface. For example, each of the first set of pins 412 can be configured to facilitate a peripheral component interconnect express (PCIe) protocol and/or a serial AT attachment (SATA) protocol.

In some embodiments, memory sub-system 320 can be enclosed in a protective case 420. The protective case 420 can have an opening 422 to expose the first set of receptacles 416 to the first set of pins 412 of test resource 310. The first set of pins 412 can be configured to connect to the first set of receptacles 416 via the opening 422 of the protective case 420.

Port 318 can further include a second set of pins 414. Each of the second set of pins 414 can be configured to transmit instructions and data between processing device 312 and memory sub-system 320. In some embodiments, each of the second set of pins 414 can be serial IO pins. In other or similar embodiments, each of the second set of pins 414 can be pins of a low speed serial interface. For example, each of the second set of pins 414 can be configured to facilitate a universal asynchronous receiver/transmitter (UART) protocol, a system management bus (SMB) protocol, or a serial wire debug (SWD protocol). Memory sub-system 320 some can include a second set of receptacles 418. In some embodiments, each of the second set of receptacles 418 can be serial IO receptacles. The second set of receptacles 418 can be configured to receive data from and/or transmit data to processing device 312. In some embodiments, opening 422 of protective case 420 can expose the second set of receptacles 418 to second set of pins 414 of port 318. The second set of pins 414 can be configured to couple to second set of receptacles 418 via the opening 422 of protective case 420.

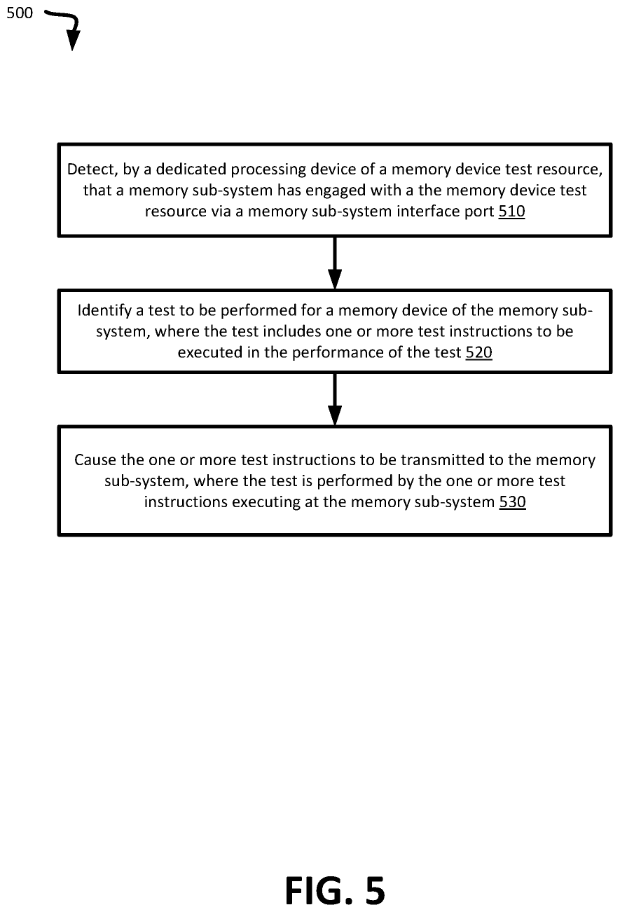

FIG. 5 is a flow diagram of an example method 500 for an intelligent memory device test rack, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by a processing device of a test resource, such as processing device 312 of FIG. 3. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing device 312 detects that a memory sub-system has engaged with a memory device test resource. For example, the memory sub-system can be memory sub-system 320 of FIG. 3. The memory sub-system 320 can engage with the test resource 310 via a memory sub-system interface port, such as port 318. Port 318 can include one or more non-serial input/output (IO) pins, such as the first set of pins 412 of FIG. 4, configured to couple to corresponding receptacles, such as the first set of receptacles 416, of the memory sub-system 320. Each of the first set of pins 412 can be configured to transmit power from the test resource 310 to the memory sub-system 320 engaged with the test resource 310. Port 318 can further include one or more serial IO pins, such as the second set of pins 414, configured to couple to corresponding serial IO receptacles, such as the second set of receptacles 418, of the memory sub-system 320. The one or more serial IO pins of the second set of pins 414 can be configured to transmit data and instructions between the processing device 312 and the memory sub-system 320 engaged with the test resource 310.

In some embodiments, the memory sub-system 320 can be enclosed within a protective case, such as memory sub-system protective case 420. The protective case 420 can include an opening 422 configured to expose the first set of receptacles 416 and the second set of receptacles 418 of the memory sub-system 320 to the first set of pins 412 and the second set of pins 414 of port 318. The first set of pins 412 and the second set of pins 414 can be configured to couple to the first set of receptacles 416 and the second set of receptacles 418 via the opening 422 of the protective case 420.

At operation 520, the processing device 312 identifies a test to be performed for a memory device, such as memory device 324, of memory sub-system 320, where the test includes one or more test instructions to be executed in the performance of the test. The memory sub-system 320 can include a memory sub-system controller, such as memory sub-system controller 322. The memory sub-system controller 322 can be responsible for performing the test for the memory device 324. In some embodiments, the one or more test instructions include one or more operations to be performed at the memory device 324, such as a read operation, a write operation, and/or an erase operation. The test instructions can further include conditions at which the test is to be performed under, referred to as a test condition. For example, the test instructions can include one or more temperature conditions and/or one or more voltage conditions to be applied to the memory sub-system 320 during the performance of the test. Each test condition can be generated by a test condition component 314 of the test resource 310. For example, the memory sub-system 320 can be subjected to a temperature condition by a temperature controller. Test conditions can be monitored by one or more test resource monitoring components, such as test resource monitoring components 316, of the test resource 310. For example, a temperature monitoring component can monitor a temperature of the memory sub-system 320 during testing. In another example, a voltage monitoring component can monitor a voltage supplied to the memory sub-system 320 via the port 318. A test resource monitoring component 316 can also include a current monitoring component configured to monitor a current of power supplied to the memory sub-system 320 via the port 318. In other or similar embodiments, a test resource monitoring component 316 can include a humidity monitoring component configured to monitor a humidity of ambient air surrounding the memory sub-system 320 during testing.

At operation 530, the processing device 312 causes the one or more test instructions to be transmitted to the memory sub-system 320 via port 318, where the test is performed by the one or more test instructions executing at the memory sub-system 320. The memory sub-system controller 322 of the memory sub-system 320 can receive the one or more test instructions and cause one or more operations of the test to be performed at the memory device 324. In some embodiments, the processing device 312 causes the operations to be performed at the memory device 324 by transmitting a signal to the memory sub-system controller 322 via the port 318 to initiate performance of the operations at the memory device 324. In other or similar embodiments, the processing device 312 causes the operations to be performed at the memory device 324 by transmitting a signal to cause the memory sub-system controller 322 to initiate a re-boot process. The one or more operations can be performed in response to the memory sub-system 320 initiating the re-boot process.

The processing device 312 can receive, via the port 318, one or more sets of test results associated with the performance of the one or more operations at the memory device 324. Each set of test results can include at least one of performance characteristics or behaviors of the memory device 324 while the test process is performed. The performance characteristics and/or the behaviors of the memory device 324 can be observed by the memory sub-system controller 322 while the one or more operations are being performed. In response to receiving the one or more sets of test results, the processing device 312 can transmit the test results to a server associated with a customer that requested the test of the memory device, such as server 220 of FIG. 2. In some embodiments, the processing device 312 can transmit, with the test results, data associated with one or more conditions monitored by a test resource monitoring component 316 of the first test resource 310A. For example, the processing device 312 can transmit data associated with at least one of a temperature of the test resource 310, a humidity of the test resource 310, a voltage of a power supply signal supplied to the memory sub-system 320, or a current of the power supply signal supplied to the memory sub-system 320 during testing of the memory device 324.

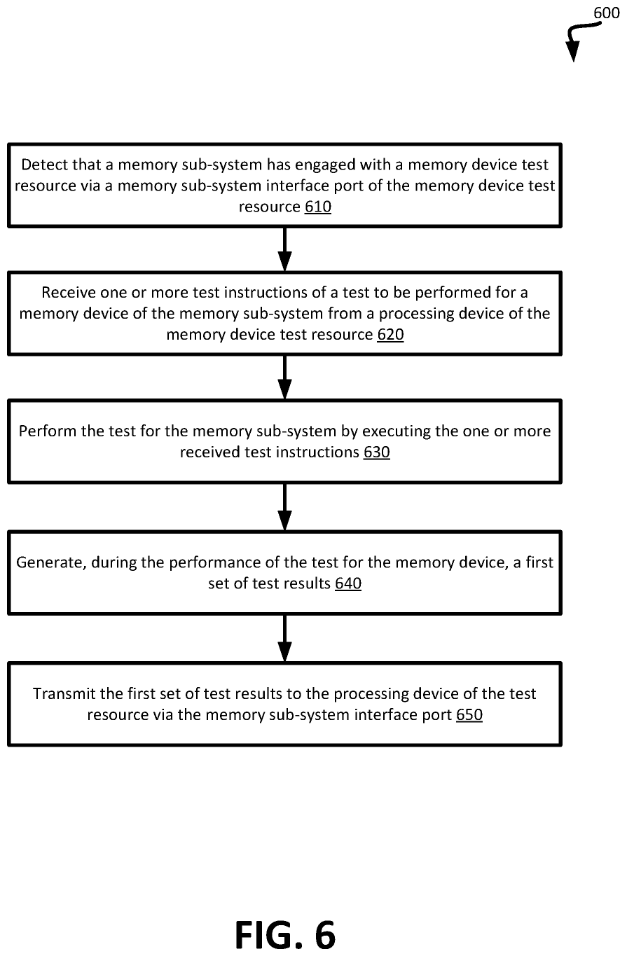

FIG. 6 is a flow diagram of an example method 600 for a memory sub-system engaged with a memory device test resource of an intelligent memory device test rack, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by the testing component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 610, the testing component 113 detects that a memory sub-system, such as memory sub-system 320 of FIG. 3, has engaged with a memory device test resource, such as test resource 310. The memory sub-system 320 can engage with the test resource 310 via a memory sub-system interface port, such as port 318, in accordance with previously described embodiments.

At operation 620, the testing component 113 receives, via the port 318, one or more test instructions of a test to be performed for a memory device, such as memory device 324, of the memory sub-system 320 from a processing device, such as processing device 312, of the test resource 310. The one or more test instructions can include operations to be performed at the memory device 324, in accordance with previously disclosed embodiments. The memory sub-system 320 can cause each operation of the one or more test instructions to be performed at the memory device 324. In some embodiments, the memory sub-system 320 can cause each operation to be performed under various test conditions, temperature conditions or voltage conditions. The temperature conditions and/or the voltage conditions can be applied to the memory sub-system 320 by a test condition component, such as test condition component 314, of the test resource 310, in accordance with previously described embodiments.

At operation 630, the testing component 113 performs a test for the memory device 324 by executing the one or more received test instructions. As previously described, a memory sub-system controller, such as memory sub-system controller 322, can perform the test by causing the performance of the one or more operations of the received test instructions. In some embodiments, the memory sub-system controller 322 can perform the test at the memory device 324 in response to receiving, via the port 318, a signal from the processing device 312 to initiate testing of the memory device 324. In other or similar embodiments, the memory sub-system controller 322 can perform the test in response to initiating a re-boot process. The memory sub-system controller 322 can initiate the re-boot process in response to receiving a signal from the processing device 312, in accordance with previously described embodiments.

At operation 640, the testing component 113 generates, during the performance of the test, a first set of test results. As previously described, the one or more test instructions for the test can include conditions at which the memory sub-system 320 is to perform the test for the memory device under. In some embodiments, the conditions can include at least a first test condition, such as a first temperature condition and/or a first voltage condition. The first set of test results can correspond to a performance of the test under the first test condition. The memory sub-system controller 322 can generate a second set of test results corresponding to a performance of one or more operations of the test instructions at the second condition.

At operation 650, the testing component 113 transmits the first set of test results to the processing device 312 via the port 318. In some embodiments, the processing device 312 further transmits the second set of test results generated based on the performance of one or more operations at the second condition, in accordance with previously described embodiments. In response to receiving the first set of test results and/or the second set of test results, the processing device 312 can cause the received test results to be transmitted to a server, such as server 220 of FIG. 2, in accordance with previously described embodiments.

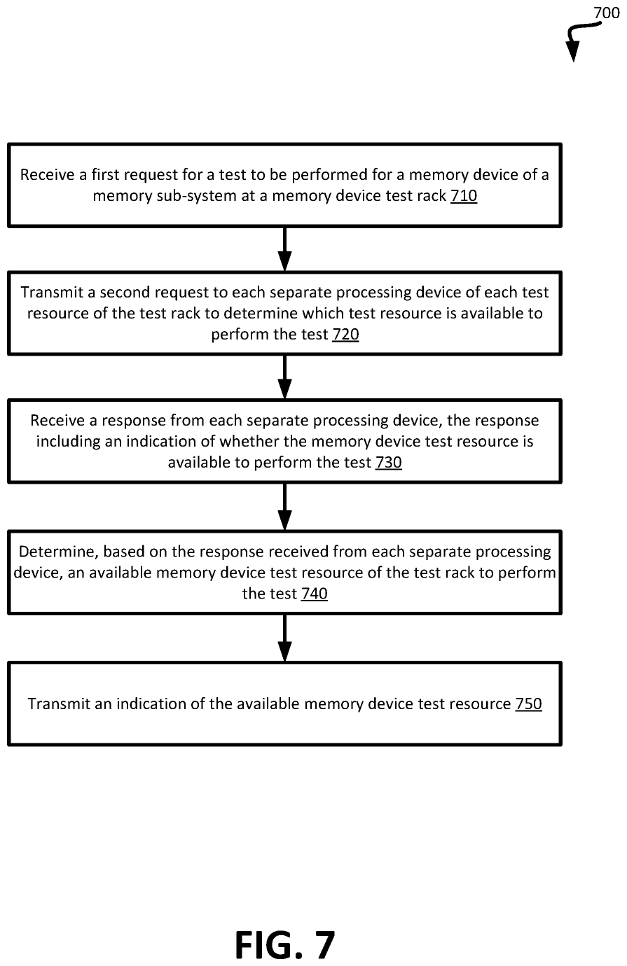

FIG. 7 is a flow diagram of an example method 700 for a resource allocator operatively coupled to each processing device of a test board of a test rack, in accordance with some embodiments of the present disclosure. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the resource allocator component 222 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 710, the processing logic receives a first request for a test to be performed for a memory device of a memory sub-system at a memory device test rack. In some embodiments, the memory sub-system can be memory sub-system 320 of FIG. 3, and the memory device can be memory device 324. In some embodiments, the memory device test rack can be any of test rack 210A, B, or C of FIG. 2. The test rack 210 can include two or more memory device test resources, such as test resources 312 of FIG. 3. Each test resource 310 can include a dedicated processing device, such as processing device 312, where the processing device 312 is dedicated to facilitate memory device testing at the test resource 310. Each test resource 310 can further include a test condition component, such as test condition component 314. In some embodiments, the first request can include one or more operations corresponding to a test condition to be applied to the memory sub-system 320 during the test.

At operation 720, the processing logic transmits a second request to each separate processing device 312 of each test resource 310 to determine which test resource 310 is available to perform the test. At operation 730, the processing logic receives a response from each separate processing device 312, the response including an indication of whether the test resource 310 is available to perform the test. In some embodiments the response can include an indication of a test condition component 314 included in the test resource 310. For example, the processing logic can receive, from a first processing device 312 of a first test resource 310, a first response that indicates the first test resource 310 is available and the first test resource 310 includes a temperature controller and a voltage controller. The processing logic can also receive, from a second processing device 312 of a second test resource 310, a second response that indicates the second test resource 310 is available and the second test resource 310 includes a temperature controller.

At operation 740, the processing logic determines, based on the response received from each separate processing device, an available test resource 310 of the test rack 212 to perform the test. In some embodiments, the available test resource 310 can be further determined based on an indication of whether the available test resource 310 includes a test condition component 314 configured to generate the test condition included in the first request. In accordance with the previous example, the first request can include one or more operations corresponding to a voltage of a power supply signal provided to the memory sub-system 320 by the available test resource 310. The processing logic can select the available test resource 310 for the test based on an indication of the first response that the first test resource 310 includes a voltage controller.

At operation 750, the processing logic transmits an indication of the available test resource 310. In response to receiving an indication of the available test resource 310, the memory sub-system can be coupled to the available test resource 310 for testing. For example, the processing logic can transmit the indication of the available test resource 310 to an operator of the test rack 210. In response to receiving the indication, the operator can cause the memory sub-system 320 to be coupled to the available test resource 310 for testing.

In some embodiments, the processing logic can receive one or more operations to be performed during the test for the memory device. The operations can include a test condition generated by a test condition component 314 of the available test resource 310. In some embodiments, the test condition can include a temperature of ambient air surrounding the memory sub-system 320 or a voltage of a power supply signal provided to the memory sub-system 320. The operations can further include or one or more of a read operation, a write operation, or an erase operation performed at the memory device 324 during the test. In response to receiving the one or more operations, the processing logic can transmit one or more test instructions including the one or more operations to the processing device 312 allocated to the available test resource 310. In some embodiments, the one or more test instructions can be generated by the processing logic. In some embodiments, the one or more test instructions are transmitted to the processing device 312 in response to receiving an indication that the memory sub-system 320 has coupled to the available test resource 310 via a memory sub-system interface port, such as port 318, of the available test resource 310.

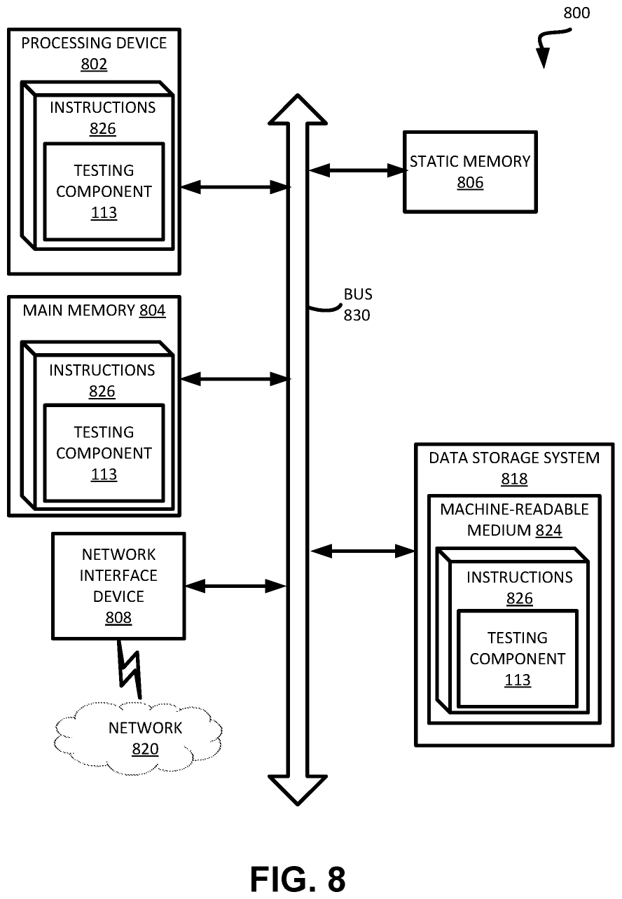

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the testing component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 708 to communicate over the network 820.

The data storage system 818 can include a machine-readable storage medium 824 (also known as a computer-readable medium) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1.

In one embodiment, the instructions 826 include instructions to implement functionality corresponding to a testing component (e.g., the testing component 113 of FIG. 1). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device test resource comprising:
a dedicated processing device for the memory device test resource, the dedicated processing device configured to facilitate testing of a memory device of a memory sub-system coupled to the memory device test resource;
a memory sub-system interface port coupled to the dedicated processing device and configured to couple the memory device test resource to the memory sub-system;
a test condition component coupled to the dedicated processing device and configured to generate a test condition at the memory device test resource;
a test resource monitoring component coupled to the dedicated processing device and configured to monitor one or more conditions at the memory device test resource.

2. The memory device test resource of claim 1, wherein the dedicated processing device is configured to perform operations comprising:
detecting that the memory sub-system has coupled to the memory device test resource;
identifying a test to be performed for the memory device of the memory sub-system, wherein the test comprises one or more test instructions to be executed in performance of the test; and
causing the one or more test instructions to be transmitted to the memory sub-system, wherein the test is performed by the one or more test instructions executing at the memory sub-system.

3. The memory device test resource of claim 2, wherein the dedicated processing device is configured to perform operations further comprising:
receiving, from the memory sub-system, a first set of test results for the test performed for the memory device.

4. The memory device test resource of claim 1, wherein the memory sub-system interface port comprises a first set of serial input/output (IO) pins configured to couple to corresponding serial IO receptacles of the memory sub-system and a second set of IO pins configured to couple to corresponding IO receptacles of the memory sub-system, and wherein one or more test instructions of a test to be performed at the memory device are transmitted to the memory sub-system via the first set of serial IO pins of the memory sub-system interface port.

5. The memory device test resource of claim 1, wherein the dedicated processing device is configured to perform operations comprising:
causing the test condition component to generate a first test condition to be applied to the memory sub-system based on one or more test instructions of a test to be performed for the memory device; and
receiving, from the test resource monitoring component, data associated with one or more conditions within the memory device test resource, wherein the one or more conditions comprise the first test condition generated by the test condition component.

6. The memory device test resource of claim 5, wherein the dedicated processing device is configured to perform operations comprising:
cause the test condition component to generate a second test condition to be applied to the memory sub-system while the test is performed at the memory device; and
receive, from the memory sub-system, a first set of test results for the test performed for the memory device under the first test condition and a second set of test results for the test performed for the memory device under the second test condition.

7. The memory device test resource of claim 1, wherein the test condition component comprises at least one of a temperature controller or a voltage controller, and the test resource monitoring component comprises at least one of a temperature monitoring component, a voltage monitoring component, a current monitoring component, or a humidity monitoring component.

8. A system comprising:
a memory device; and
a processing device operatively coupled to the memory device, the processing device to perform operations comprising:
receiving, from a requestor, a first request for a test to be performed for a memory device of a memory sub-system at a memory device test rack, wherein the memory device test rack comprises a plurality of memory device test resources each comprising a separate processing device;
transmitting a second request to each separate processing device to determine which of the plurality of memory device test resources are available to perform the test for the memory device of the memory sub-system;
receiving a response from each separate processing device, the response comprising an indication of whether each of the plurality of memory device test resources are available to perform the test;
determining, based on the response received from each separate processing device, an available memory device test resource of the memory device test rack to perform the test; and
transmitting, to the requestor, an indication of the available memory device test resource.

9. The system of claim 8, wherein the processing device is to perform operations further comprising:
receiving, from the requestor, one or more operations to be performed during the test for the memory device of the memory sub-system;
transmitting one or more test instructions comprising the one or more operations to the separate processing device allocated to the available memory device test resource.

10. The system of claim 9, wherein the one or more test instructions are transmitted to the separate processing device responsive to receiving an indication that the memory sub-system has coupled to the available memory device test resource via a memory sub-system interface port of the available memory device test resource.

11. The system of claim 9, wherein the one or more operations correspond to at least one of a test condition generated by a test condition component of the available memory device test resource during the test, or one or more of a read operation, a write operation, or an erase operation performed at the memory device during the test.

12. The system of claim 11, wherein the test condition comprises at least one of a temperature of ambient air surrounding the memory sub-system or a voltage of a power supply signal provided to the memory sub-system by the available memory device test resource.

13. The system of claim 8, wherein the first request for the test to be performed for the memory device comprises one or more operations corresponding to a test condition to be applied to the memory sub-system during the test and wherein the available memory device test resource is further determined based on an indication of whether the available device test resource comprises a test condition component configured to generate the test condition during the test.

14. A test rack comprising:
a first memory device test resource comprising a first processing device, wherein the first processing device is configured to facilitate performance of a test for a memory device of a memory sub-system coupled to the first memory device test resource; and
a second memory device test resource comprising a second processing device, wherein the second processing device is configured to facilitate performance of the test at the memory device of the memory sub-system coupled to the second memory device test resource responsive to the first processing device of the first memory device test resource being unavailable to facilitate the performance of the test.

15. The test rack of claim 14, wherein the first processing device is to perform operations comprising:
detecting that the memory sub-system has engaged with the first memory device test resource;
identifying the test to be performed for the memory device of the memory sub-system, wherein the test comprises one or more test instructions to be executed in performance of the test; and
causing the one or more test instructions to be transmitted to the memory sub-system, wherein the test is performed by the one or more test instructions executing at the memory sub-system.

16. The test rack of claim 15, wherein the first processing device is to perform operations comprising:
receiving, from the memory sub-system, a first set of test results for the test performed for the memory device.

17. The test rack of claim 15, wherein the first processing device is to perform operations further comprising:
causing a test condition component of the first memory device test resource to generate a first test condition to be applied to the memory sub-system based on the one or more test instructions for the test to be performed for the memory device; and
receiving, from a test resource monitoring component of the first memory device test resource, data associated with one or more conditions within the first memory device test resource, wherein the one or more conditions comprise the first test condition generated by the test condition component.

18. The test rack of claim 17, wherein the test condition component comprises at least one of a temperature controller or a voltage controller and the test resource monitoring component comprises at least one of a temperature monitoring component, a voltage monitoring component, a current monitoring component, or a humidity monitoring component.

19. The test rack of claim 14, wherein the first processing device is to perform operations comprising:
transmitting, to a memory device test resource allocator, a notification that the first processing device is unavailable to facilitate performance of the test at the first memory device test resource.

20. The test rack of claim 19, wherein the second processing device is to perform operations comprising:
receiving a request to facilitate performance of the test at the second memory device test resource;
detecting that the memory sub-system has engaged with the second memory device test resource;
identifying a test to be performed for the memory device of the memory sub-system wherein the test comprises one or more test instructions to be executed in performance of the test; and
causing the one or more test instructions to be transmitted to the memory sub-system, wherein the test is performed by the one or more test instructions executing at the memory sub-system.
